(19) United States
(12) Patent Application Publication
(10) Pub. No.: US 2006/0216548 A1
(43) Pub. Date: Sep. 28, 2006

(54) Nanolaminate thin films and method for forming the same using atomic layer deposition

(76) Inventors: Ming Mao, Pleasanton, CA (US); Randhir Bubber, Fremont, CA (US); Thomas Andrew Schneider, Livermore, CA (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/086,133

(22) Filed: Mar. 22, 2005

(51) Int. Cl. C23C 16/00; B32B 9/00

(52) U.S. Cl. 428/701; 428/702; 427/248.1; 427/402

(57) ABSTRACT

A nanolaminate thin film and a method for forming the same using atomic layer deposition are disclosed. The method includes forming an aluminum oxide layer having a first thickness on at least a portion of a substrate surface by sequentially pulsing a first precursor and a first reactant into an enclosure containing the substrate. A layer of silicon dioxide is formed on at least a portion of the aluminum oxide layer by sequentially pulsing a second precursor and a second reactant into the enclosure to form a nanolaminate thin film.

### TECHNICAL FIELD OF THE INVENTION

The present invention generally relates to film deposition, and more particularly to a nanolaminate thin film and method for forming the same using atomic layer deposition.

### BACKGROUND OF THE INVENTION

Atomic layer deposition (ALD), also known as sequential pulsed chemical vapor deposition (SP-CVD), atomic layer epitaxy (ALE) and pulsed nucleation layer (PNL) deposition, has gained acceptance as a technique for depositing thin and continuous layers of metals and Dielectrics with high conformality. In an ALD process, a substrate is alternately dosed with a precursor and one or more reactant gases so that reactions are limited to the surface of a substrate. Thus, gas phase reactions are avoided since the precursor and the reactant gases do not mix in the gas phase. Uniform adsorption of precursors on the wafer surface during the ALD process produces highly conformal layers at both microscopic feature length scales and macroscopic substrate length scales, and achieves a high density of nucleation sites. These attributes result in the deposition of spatially uniform, conformal, dense and continuous thin films.

The high quality films achievable by ALD have resulted in increased interest in ALD for the deposition of conformal barriers, high-k dielectrics, gate dielectrics, tunnel dielectrics and etch stop layers for semiconductor devices. ALD films are also thermally stable and very uniform which makes them attractive for optical applications. Another potential application for ALD is the deposition of oxides (e.g., Al₂O₃) as a gap layer for thin film heads, such as heads for recording densities of 50 Gb/in² and beyond which require very thin and conformal gap layers.

As recording densities for hard disk drives continue to increase, the thickness of gap layers required for read heads used in the disk drives decreases. For example, the thickness of the gap layer required for a read head in a hard disk drive having a recording density of approximately 100 Gb/in² should be significantly below 200 angstroms (Å). The gap layer should also have a high dielectric strength, a low internal stress and a high resistance to resist developer etch. In general, oxide and nitride films, such as Al₂O₃ and aluminum nitride (AlN), formed by an ALD process have produced high quality gap layers for read head applications. At thicknesses below 200 Å, however, Al₂O₃ films typically have a lower dielectric strength and are more susceptible to resist developer etch.

In addition, conventionally sputtered gap layers may not be suitable for higher recording densities because they are difficult to reliably scale below 300 Å due to excessive leakage currents. Although ion beam deposited gap layers can be scaled down in thickness to below 300 Å, such layers tend not to be adequately conformal. Further, process integration considerations for thin film heads of 200 Å or less may constrain the maximum deposition temperature to below 200° C.

### SUMMARY OF THE INVENTION

In accordance with the present invention, the disadvantages and problems associated with fabricating a high quality nanolaminate thin film have been substantially reduced or eliminated. In a particular embodiment, a method is disclosed for forming a nanolaminate thin film of aluminum oxide and silicon dioxide on a substrate surface.

In accordance with one embodiment of the present invention, a method for forming a nanolaminate thin film using ALD includes forming an aluminum oxide layer having a first thickness on at least a portion of a substrate surface by sequentially pulsing a first precursor and a first reactant into an enclosure containing the substrate. A silicon dioxide layer having a second thickness is formed on at least a portion of the aluminum oxide layer by sequentially pulsing a second precursor and a second reactant into the enclosure to form a nanolaminate thin film.

In accordance with another embodiment of the present invention, a method for forming a nanolaminate thin film using ALD includes forming an aluminum oxide layer having a first thickness on at least a portion of a substrate surface by sequentially pulsing trimethylaluminum (TMA) and water into an enclosure containing the substrate. A silicon dioxide layer having a second thickness is formed on at least a portion of the aluminum oxide layer by sequentially pulsing TMA and tris(tert-butoxy)silanol into the enclosure to form a read head gap layer.

In accordance with a further embodiment of the present invention, a thin film includes an ALD-formed aluminum oxide layer having a first thickness and an ALD-formed silicon dioxide layer having a second thickness formed on at least a portion of the aluminum oxide layer. The aluminum oxide layer and the silicon dioxide layer cooperate to form a nanolaminate thin film.

Important technical advantages of certain embodiments of the present invention include nanolaminate films formed using an ALD process that have high dielectric breakdown strengths. For certain applications, such as gap fill layers in read heads included in hard disk drives, the thickness of the film should be below a minimum value and the film should have certain characteristics. Single layer oxide films, such as aluminum oxide (Al₂O₃), may have lower breakdown fields at thickness below, for example, approximately 200 Å. A nanolaminate of Al₂O₃ and silicon dioxide (SiO₂) having a thickness at or below approximately 200 Å, however, has a higher breakdown field due to the addition of SiO₂ to the film and may be used to form high quality gap layers for read heads of high density hard disks.

Another important technical advantage of certain embodiments of the present invention includes nanolaminate films formed using an ALD process that have high resistances to resist developer etch. During fabrication of microelectronic structures, an etch process may be used to remove one or more materials from a surface. In a read head in a hard disk drive, for example, a resist layer may be removed to expose the surface of an underlying oxide material used to form a gap fill layer in the read head. For hard disks having higher recording densities, it may be desirable to have a thin gap layer (e.g., below 200 Å) and, in order to maintain the required thickness of the gap layer, the material should be resistant to resist developer etch. An Al₂O₃ film formed by an ALD process, however, may not be resistant to the etch process such that the etch process decreases the thickness of the film and degrades other desired properties. In contrast, SiO₂ is much more resistant to an etch process and may be used to form a Al₂O₃/SiO₂ nanolaminate such that almost none of the nanolaminate film is removed by the etch process.

A further important technical advantage of certain embodiments of the present invention includes nanolaminate films formed using an ALD process that have lower film stress. In many applications, it may be important for a thin film to have low stress. Single layer Al₂O₃ films formed using an ALD process may exhibit a high tensile stress, which is undesirable for applications such as gap layers of read heads in hard disk drives. SiO₂ films formed using the ALD process, however, typically have a low tensile or compressive stress. Therefore, the film stress of an Al₂O₃/SiO₂ nanolaminate may be controllably reduced by adding SiO₂ to decrease the Al₂O₃ concentration of the film.

All, some, or none of these technical advantages may be present in various embodiments of the present invention. Other technical advantages will be readily apparent to one skilled in the art from the following figures, descriptions, and claims.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a schematic diagram of an atomic layer deposition (ALD) system for forming a conformal thin film on a substrate according to teachings of the present invention;

FIG. 2 illustrates a schematic diagram of an inner shield assembly located in a vacuum chamber of the ALD system of FIG. 1;

FIG. 3 illustrates a cross sectional view of a thin film magnetic read head fabricated by using an ALD process according to teachings of the present invention;

FIG. 4 illustrates a graph of rate of deposition of a single layer of aluminum oxide (Al₂O₃) and a single layer of silicon dioxide (SiO₂) formed by an ALD process as a function of deposition temperature according to teachings of the present invention;

FIG. 5 illustrates a graph of saturation characteristics for the deposition of a thin film formed by an ALD process as a function of reactant pulsing time according to teachings of the present invention;

FIG. 6A illustrates a graph of dielectric breakdown characteristics for a 200 Å single layer of SiO₂ film deposited at different deposition temperatures using an ALD process according to teachings of the present invention;

FIG. 6B illustrates a graph of dielectric breakdown characteristics for a 200 Å single layer of Al₂O₃ film deposited at different deposition temperatures using an ALD process according to teachings of the present invention;

FIG. 7A illustrates a graph of dielectric breakdown characteristics for an Al₂O₃/SiO₂ nanolaminate formed by an ALD process at different Al₂O₃ compositions according to teachings of the present invention;

FIG. 7B illustrates a graph of dielectric breakdown field for an Al₂O₃/SiO₂ nanolaminate formed by an ALD process as a function of Al₂O₃ composition at different leakage current density thresholds according to teachings of the present invention;

FIG. 8A illustrates a graph of dielectric breakdown characteristics for an Al₂O₃/SiO₂ nanolaminate and a single layer of Al₂O₃ formed by an ALD process for different film thicknesses according to teachings of the present invention;

FIG. 8B illustrates a graph of dielectric breakdown field for an Al₂O₃/SiO₂ nanolaminate and a single layer of Al₂O₃ formed by an ALD process as a function of film thickness according to teachings of the present invention;

FIG. 9A illustrates a graph of resist developer etch rates for a single Al₂O₃ film and an Al₂O₃/SiO₂ nanolaminate formed by an ALD process as a function of substrate temperature during deposition according to teachings of the present invention;

FIG. 9B illustrates a graph of resist developer etch rates for a thin film formed by an ALD process as a function of aluminum oxide concentration according to teachings of the present invention; and

FIG. 10 illustrates a graph of tensile strength of a thin film formed by an ALD process as a function of aluminum oxide concentration according to teachings of the present invention.

### DETAILED DESCRIPTION OF THE INVENTION

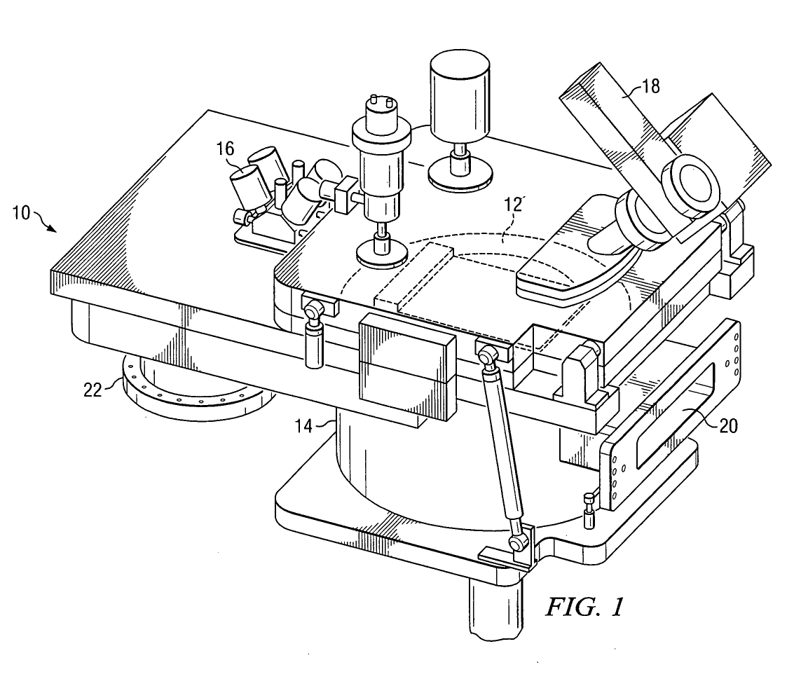

Preferred embodiments of the present invention and their advantages are best understood by reference to FIGS. 1 through 10, where like numbers are used to indicate like and corresponding parts.

The conceptual groundwork for the present invention involves an atomic layer deposition (ALD) process to create highly conformal thin films. In an ALD process, a precursor and a reactant, such as a reactant gas are sequentially pulsed onto the surface of a substrate contained in a reaction chamber, without mixing the precursor and reactant in the gas phase. Each of the precursor and the reactant reacts with the surface of the substrate to form an atomic layer in such a way that only one layer of a material forms at a time. The introduction of the precursor and/or the reactant into the reaction chamber may be referred to as a doping pulse. In between doping pulses, the reaction chamber may be purged by flowing an inert gas over the substrate. One film that may be formed using an ALD process is aluminum oxide (Al₂O₃). ALD Al₂O₃ has been used for gap fill layers of a read head included in a hard disk drive, in particular, as a second read gap over topography composed of a read sensor and hard bias/sensing leads due to the superior deposition conformality and dielectric strength of Al₂O₃. However, as recording densities continue to increase, the read heads require half read gap thickness below approximately 200 angstroms (Å).

The present invention provides a thin film that may be fabricated at lower thicknesses with higher dielectric strength and higher resistance to resist developer etch. In one embodiment, the film may be a nanolaminate of Al₂O₃ and silicon dioxide (SiO₂). Layers of Al₂O₃/SiO₂ at a thickness of less than approximately 200 Å may have an increased dielectric strength of up to approximate fourteen (14) MV/cm at an Al₂O₃ composition of less than fifty percent (50%). Additionally, Al₂O₃/SiO₂ nanolaminates have an etch resistance to resist developer that is substantially greater than the etch resistance of a single film of Al₂O₃. Although other materials, such as tantalum oxide and zirconium oxide, have been used to form nanolaminate films, the Al₂O₃/SiO₂ nanolaminates disclosed below have shown superior qualities for applications that require high dielectric strength, low film stress and high resistance to resist developer etch.

FIG. 1 illustrates atomic layer deposition (ALD) system 10 for forming a conformal thin film on a substrate. ALD system 10 may include shield assembly 12 located inside vacuum chamber 14, gas valves 16, isolation valves 18, substrate loader 20 and pump inlet 22. Shield assembly 12 may form an enclosure inside of vacuum chamber 14 such that the enclosure may contain a substrate for deposition of a thin film using an ALD process. In one embodiment, shield assembly 12 may be removable from vacuum chamber 14 such that all or portions of shield assembly 12 may be cleaned and/or replaced. The ability to remove and replace all or portions of shield assembly 12 may simplify and improve preventative maintenance and increase the lifetime of ALD system 10.

Gas valves 16 may interface with shield assembly 12. During an ALD process, a gas may be introduced into the enclosure from one or more gas reservoirs (not expressly shown) through gas valves 16. In one embodiment, the gas reservoirs may contain a precursor and/or one or more reactants used during a doping pulse. In another embodiment, the gas reservoirs may contain an inert gas that is used as a carrier gas during a doping pulse and/or that is used to remove any remaining reactants from the enclosure during a purge pulse.

During an ALD process, at least one of gas valves 16 may be opened to allow the precursor, reactant and/or inert gas to flow into the enclosure formed by shield assembly 12. The precursor, reactant and inert gas may be removed from the enclosure by opening isolation valves 18 that are interfaced with shield assembly 12 opposite gas valves 16. Isolation valves 18 may further be linked to a mechanical pump (not expressly shown) through a throttle valve (not expressly shown) that facilitates automated process pressure control during an ALD process. During a doping pulse, isolation valves 18 may be opened to allow the mechanical pump to pump the precursor or the reactant and any carrier gas through the enclosure. After the purge pulse is completed, a high speed turbo pump (not expressly shown) coupled to pump inlet 22 may be used to allow vacuum chamber 14 to quickly reach the base pressure. During a purge pulse, isolation valves 18 may be opened to allow the mechanical pump to remove any remaining precursor or reactant from the enclosure. Use of only the mechanical pump during a doping pulse to exhaust the precursor or the reactant and the carrier gas from the enclosure, therefore, may extend the operation duration and life expectancy of the turbo pump.

Substrates on which a thin film may be deposited may be loaded into vacuum chamber 14 from a central wafer handler (not expressly shown) through substrate loader 20. In one embodiment, a substrate placed in vacuum chamber 14 may be a p-type or n-type silicon substrate. In other embodiments, the substrate may be formed from gallium arsenide, an AlTiC ceramic material or any other suitable material that may be used as a substrate on which one or more material layers may be deposited. The one or more layers deposited by ALD system 10 may form films used to fabricate conformal barriers, high-k dielectrics, gate dielectrics, tunnel dielectrics and barrier layers for semiconductor devices. ALD films are also thermally stable and substantially uniform, which makes them attractive for optical applications. Another potential application for ALD is the deposition of oxides as a gap layer for thin film heads, such as heads for recording densities of 50 Gb/in² and beyond that require very thin and conformal gap layers, or as an isolation layer on an abut junction to insulate a TMR or CPP type read head from hard bias layers. Additionally, ALD thin films may be used to form structures with high aspect ratios, such as MicroElectroMechanical (MEM) structures.

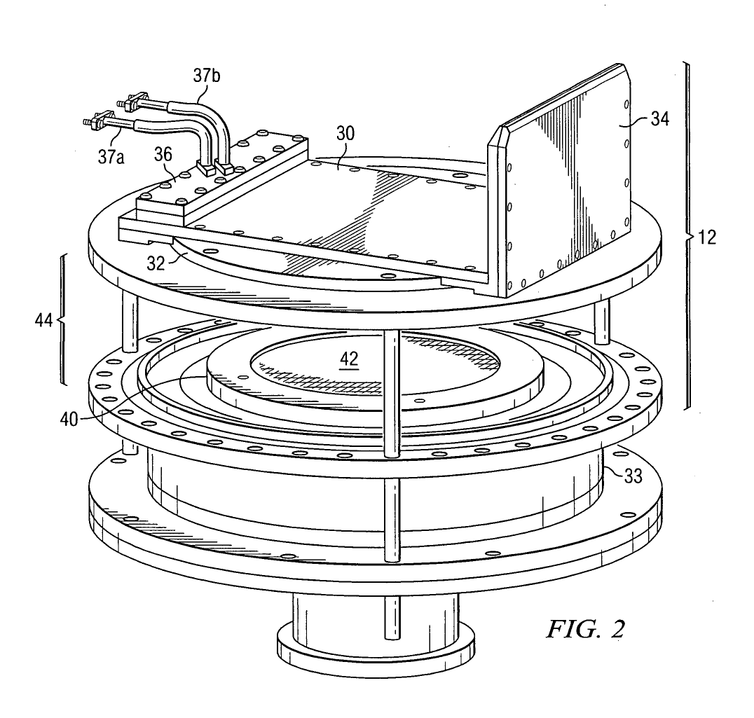

FIG. 2 illustrates shield assembly 12 that cooperates with top hat 40 to form enclosure 44 located inside vacuum chamber 14. In the illustrated embodiment, shield assembly 12 includes top shield 30, bottom shield 32, vertical shield 34 and diffuser plate 36 that are bolted together and mounted on a frame. Shield assembly 12 may facilitate preventative maintenance of ALD system 10 because portions of shield assembly 12 (e.g., top shield 30, bottom shield 32, etc.) may be individually removed and cleaned or replaced as necessary.

Top hat 40 may include substrate seat 42 for holding a substrate on which a thin film is to be deposited. Substrate seat 42 may have a depth slightly greater than or approximately equal to the thickness of a substrate. In one embodiment, substrate seat 42 may be a recess formed in top hat 40 such that substrate seat 42 is integral to top hat 40. In another embodiment, substrate seat 42 may be mounted on top hat 40 such that substrate seat 42 is separate from top hat 40. Top hat 40 may be mounted on chuck 38 located in vacuum chamber 14. Chuck 38 may function to control the position of substrate seat 42 within vacuum chamber 14 and the position of top hat 40 in relation to shield assembly 12. In one embodiment, chuck 38 includes a heating mechanism with a temperature control and constant backside gas flow to a substrate located in substrate seat 42. The temperature control with constant backside gas flow may ensure fast heating and temperature uniformity across a substrate positioned in substrate seat 42. In another embodiment, chuck 38 includes a RF power application mechanism, which allows in-situ RF plasma processing.

Enclosure 44 may be defined by the position of shield assembly 12 in relation to top hat 40. In one embodiment, enclosure 44 may be formed when top hat 40 is in contact with bottom shield 32 such that enclosure 44 has a volume defined by substrate seat 42 and the thickness of bottom shield 32. When top hat 40 is contacting bottom shield 32 of shield assembly 12, the volume of enclosure 44 may be approximately three (3) to approximately five (5) times the volume of the substrate. Deposition of the thin film on the substrate may occur on the entire substrate surface without edge exclusion but may be confined only to enclosure 44. By minimizing the volume of enclosure 44, a minimum amount of precursor may be efficiently distributed in a minimum amount of time over the entire surface of the substrate. Additionally, surplus reactants and any reaction byproducts may be quickly removed from enclosure 44 to reduce the possibility of unwanted reactions from occurring inside enclosure 44.

In another embodiment, enclosure 44 may have a volume approximately equal to the volume of vacuum chamber 14 when chuck 38 is in the loading position (e.g., chuck 38 is at its lowest position in vacuum chamber 14). In other embodiments, the volume of enclosure 44 may depend on the distance between bottom shield 32 and top hat 40 such that the volume is varied between approximately fifty milliliters (50 ml) when top hat 40 is in close proximity to bottom shield 32 of shield assembly 12 to approximately twenty liters (20 l) when chuck 38 is in the substrate loading position.

Gas lines 37a and 37b (generally referred to as gas lines 37) may be connected to diffuser plate 36. During a purge pulse, gas valves 16 may be open to allow a gas to flow through one or both of gas lines 37a and 37b from gas reservoirs (not expressly shown). The gas then flows through diffuser plate 36 included in a gas injector located between diffuser plate 36 and top shield 30. In one embodiment, gas lines 37 may be formed of stainless steel and have a diameter of approximate one-quarter (¼) inch. Although the illustrated embodiment shows a particular number of gas lines, ALD system 10 may include any number of gas lines and any number of gas reservoirs. For example, a single gas line may be connected to multiple gas reservoirs such that the gas flowing through the gas line is controlled by one or more valves. In another embodiment, a separate gas line may be provided for each gas reservoir.

The thin film may be formed on a substrate by alternately flowing a precursor and one or more reactants combined with an inert gas during a doping pulse and the inert gas during a purge pulse through gas lines 37 and into enclosure 44. For example, the precursor may be introduced into enclosure 44 through gas lines 37 and may be chemisorbed onto the surface of a substrate to form a single, monolayer of film. Enclosure 44 may be purged by flowing a purge gas through gas lines 37 and into enclosure 44 to remove any remaining precursor. After purging, the reactant be introduced into enclosure 44 through gas lines 37 and may combine with the chemisorbed monolayer of precursor to form an atomic layer of the desired thin film. Again, enclosure 44 may be purged to remove any of the remaining reactant. The doping and purge pulses may be repeated until a thin film having the desired thickness is formed on the substrate.

As illustrated, the reactants and/or inert gas may be injected into enclosure 44 from one end of top shield 30 and exhausted at the other end through vertical shield 34. Vertical shield 34 may be coupled to isolation valves 18 (as illustrated in FIG. 1) and a mechanical pump (not expressly shown) that assists with the removal of the precursor and/or inert gas from enclosure 44.

In one embodiment, ALD system 10 may be used to form an aluminum oxide (Al₂O₃)/silicon dioxide (SiO₂) nanolaminate on a substrate. The Al₂O₃ layer may be formed by sequentially pulsing a precursor and a reactant into enclosure 44. The precursor may be vapor-phase pulses of an aluminum source chemical and the reactant may be an oxygen source chemical. In a specific embodiment, the aluminum source chemical may be trimethylaluminum (TMA) and the oxygen source chemical may be selected from the group containing water (H₂O), ozone (O₃) or an oxygen radical (O₂). In other embodiments, the aluminum source chemical may be any aluminum compound that is volatile at the source temperature and thermally stable at the substrate temperature and the oxygen source material may be any volatile or gaseous compounds that contain oxygen and are capable of reacting with an adsorbed portion of the selected aluminum source compound on the substrate surface at the deposition conditions such that an Al₂O₃ thin film is deposited on the substrate surface.

The SiO₂ layer may also be formed by sequentially pulsing a precursor and a reactant into enclosure 44. The precursor may be vapor-phase pulses of an aluminum source chemical that produces aluminum to catalyze the growth of a SiO₂ film and the reactant may be a silicon source chemical. In a specific embodiment, the aluminum source chemical may be TMA and the silicon source chemical may be tris(tert-butoxy)silanol ([Bu^{t}O]₃SiOH), tris(tert-pentoxy)silanol or tris(iso-propoxy)silanol. In other embodiments, the aluminum source chemical may be any aluminum compound that is volatile at the source temperature and thermally stable at the substrate temperature, which produces aluminum to catalyze the growth of a SiO₂ film, and the silicon source chemical may be any volatile alkoxy organosilicon compound that is thermally stable at the deposition temperature.

An inert gas may be used as a carrier gas to convey the precursor and reactant during a doping pulse and as a purge gas to remove any remaining reactants from enclosure 44 during a purge pulse. In one embodiment, the inert gas may be Argon (Ar). In other embodiments, the inert gas may be any suitable inactive gas.

Nanolaminates of [xAl₂O₃/ySiO₂]ₙ may be synthesized by pulsing a TMA precursor and an oxygen based reactant (e.g., H₂O) into enclosure 44 to form a layer of Al₂O₃ and pulsing a TMA precursor and a butoxy silanol reactant into enclosure 44 to form a layer of SiO₂. The Al₂O₃ composition of the nanolaminate film may be adjusted between approximately zero (0) and approximately one-hundred (100) percent by varying x and y. Film thickness may be adjusted by varying the number (n) of Al₂O₃ and SiO₂ cycles.

In one embodiment, alternating layers of Al₂O₃ and SiO₂ may be formed by alternating Al₂O₃ and SiO₂ deposition cycles until an Al₂O₃/SiO₂ nanolaminate having a desired thickness is formed. The deposition process may begin with either a layer of Al₂O₃ or a layer of SiO₂. The thickness of each Al₂O₃ layer may be approximately the same or each layer may have a different thickness. Additionally, the thickness of each SiO₂ layer may be approximately the same or each layer may have a different thickness. The total number of Al₂O₃ layers and SiO₂ layers may depend on the desired thickness for the nanolaminate film. In another embodiment, a layer of SiO₂ may be formed over a layer of Al₂O₃ having a specific thickness by performing one or more Al₂O₃ deposition cycles before performing a SiO₂ deposition cycle. In a further embodiment, the nanolaminate film may have an odd number of material layers formed on a substrate surface where either the Al₂O₃ layer or the SiO₂ layer may be the top layer of the film. If the nanolaminate film includes multiple Al₂O₃ layers, the thickness of each Al₂O₃ layer may be approximately the same or each layer may have a different thickness. If the nanolaminate film includes multiple SiO₂ layers, the thickness of each SiO₂ layer may be approximately the same or each layer may have a different thickness. Again, the total number of material layers may depend on the desired thickness for the nanolaminate film.

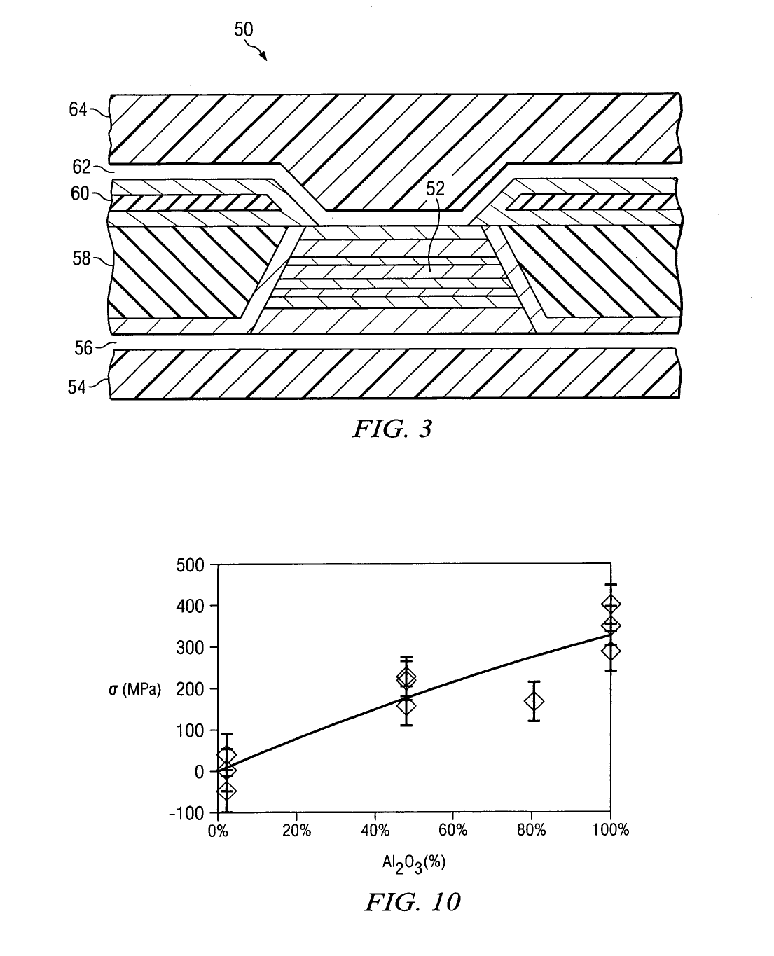

FIG. 3 illustrates a cross-sectional view of a thin film magnetic read head including an oxide gap fill layer formed by using an ALD process. A magnetic thin film read head, illustrated generally at 50, includes read sensor 52 located in between two gap fill layers 56 and 62. Gap fill layer 56 may be formed on bottom shield layer 54 and top shield layer 64 may be formed on gap fill layer 62. Read 52 may include multiple layers of different magnetic and non-magnetic layers. In one embodiment, read 52 may be a multilayer giant magnetoresistive (GMR) device or a spin valve device. In other embodiments, read sensor 52 may be any type of magnetoresistive device used in a read head for a hard disk drive. Read head 50 may further include lead 60 and hard bias layer 58 that surround read sensor 52. Lead 60 may function as an electrically conductive electrode layer.

The thickness of gap fill layers 56 and 62 may be used to control the linear recording density of a hard disk drive including read head 50. Additionally, gap fill layers 56 and 62 may provide insulation for read sensor 52 and may dissipate heat throughout read head 50. As the recording densities for disk drives increase, the thickness of gap fill layers 56 and 62 should decrease. Additionally, reducing the thickness of gap fill layers 56 and 62 may improve the heat dissipation of read head 50. Although Al₂O₃ has traditionally been used as a gap fill layer, Al₂O₃ films may be unable to retain certain properties (e.g., a high dielectric breakdown strength) if the film is less than a certain thickness.

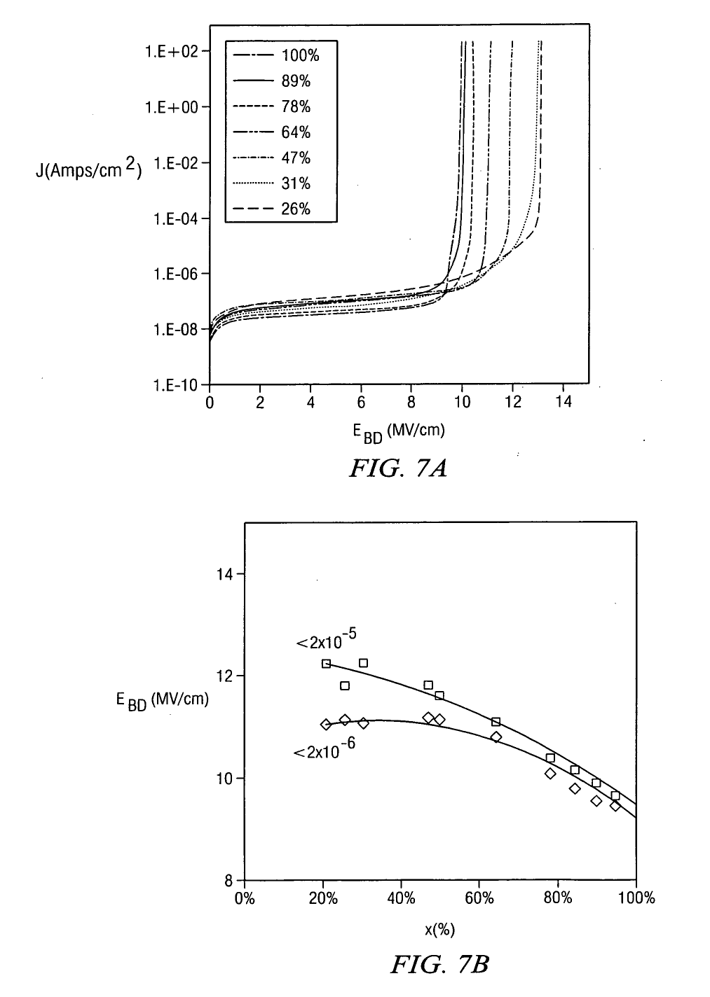

A nanolaminate of Al₂O₃ and SiO₂, however, may be used to form gap layers 56 and 62 having decreased thicknesses because the addition of SiO₂ allows the film to maintain certain characteristics as the thickness decreases. In one embodiment, gap layers 56 and 62 may have a thickness of between approximately fifty angstroms (50 Å) and approximately 250 Å. At a thickness of 250 Å, an Al₂O₃/SiO₂ nanolaminate thin film may have a dielectric breakdown field of approximately 13 MV/cm where as a single layer of Al₂O₃ may have a dielectric breakdown field of approximately 10 MV/cm. Even for a thickness at or below 50 Å, for example, an Al₂O₃/SiO₂ nanolaminate may have a dielectric breakdown field of approximately 11 MV/cm where as a single layer of Al₂O₃ may only have a dielectric breakdown field of approximately 8 MV/cm. Other properties of an Al₂O₃/SiO₂ nanolaminate thin film are shown in more detail below with respect to FIGS. 7 through 10.

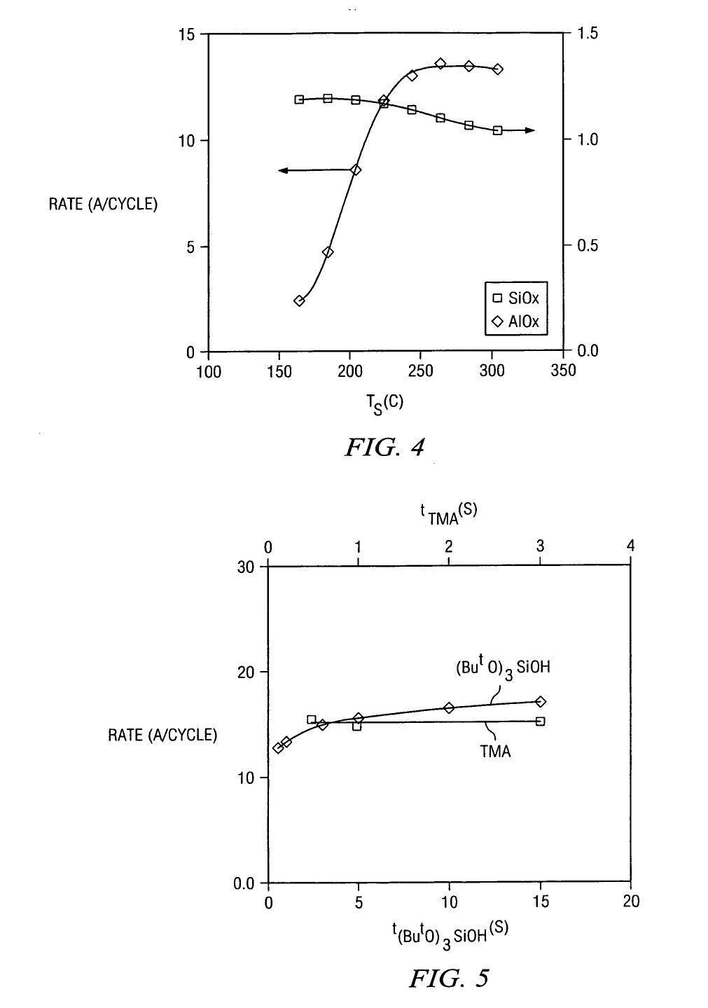

FIG. 4 illustrates a graph of rate of deposition of Al₂O₃ (as shown along the right y-axis) and SiO₂ (as shown along the left y-axis) using an ALD process as a function of temperature. As illustrated, a layer of Al₂O₃ may be deposited with an ALD process at a relatively constant growth rate of approximately 1.05 Å/cycle when the substrate temperature is between approximately 150° C. and 300° C. The deposition rate of ALD SiO₂ thin films may increase from approximately 2.4 A/cycle at a substrate temperature of approximately 150° C. to a plateau of approximately 13 Å/cycle at a substrate temperature above approximately 210° C.

FIG. 5 illustrates a graph of saturation characteristics for the deposition of SiO₂ thin films by using an ALD process as a function of pulsing time in seconds of the TMA reactant (as shown along the top x-axis) and the butoxy silanol reactant (as shown along the bottom x-axis) used in the process. During deposition of the film, the source temperature for each reactant was approximately 95° C. and the substrate temperature was approximately 210° C. Charging and pulsing of (Bu^{t}O)₃SiOH were manipulated such that exposures to alternating pulses of TMA/(Bu^{t}O)₃SiOH at appropriate partial pressures produced a deposition rate for the SiO₂ layer below approximately 15 Å/cycle, which may be desirable for the formation of nanolaminate films.

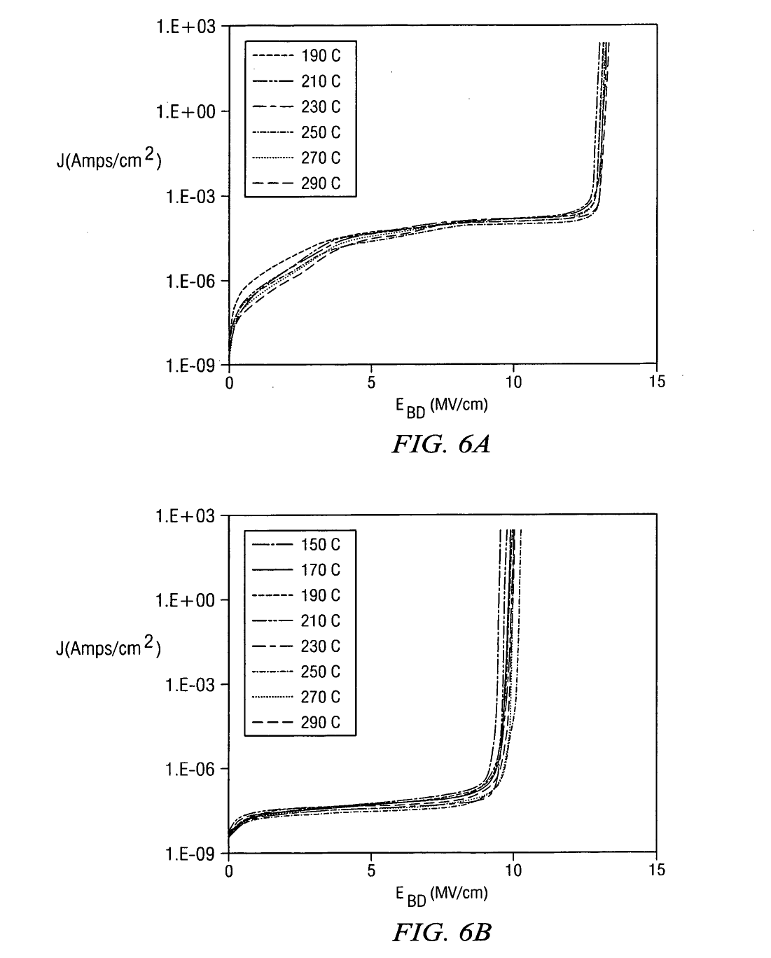

FIGS. 6A and 6B illustrate graphs of dielectric breakdown characteristics for a 200 Å single layer of aluminum oxide and a 200 Å single layer of silicon dioxide when deposited at different deposition temperatures. As illustrated in FIG. 6A, the dielectric breakdown characteristics were measured at six different deposition temperatures ranging from approximately 190° C. to approximately 290° C. The dielectric breakdown for a single layer of SiO₂ over the deposition temperature range may occur at a breakdown field (EBD) of approximately 12.5 MV/cm and a leakage current density (J) of approximately 1×10⁻⁴ Amps/cm².

In comparison, a single layer of Al₂O₃ shows a lower dielectric break down over the range of deposition temperatures as illustrated by FIG. 6B. As shown, the dielectric breakdown characteristics for Al₂O₃ deposition were measured at eight different temperatures ranging from approximately 150° C. to approximately 290° C. The dielectric breakdown for Al₂O₃ may occur at a breakdown field (EBD) of approximately 9.3 MV/cm and a leakage current density (J) of approximately 1×10⁻⁷ Amps/cm². In some applications, such as read heads, a higher dielectric strength may be desirable.

FIGS. 7A and 7B illustrates graphs of dielectric breakdown characteristics for a nanolaminate layer of Al₂O₃/SiO₂ deposited using an ALD process as a function of Al₂O₃ concentration. As illustrated in FIG. 7A, the dielectric breakdown characteristics were measured for nanolaminate thin films having an Al₂O₃ concentration ranging from approximately 26% to approximately 100%. The dielectric strength of the nanolaminate thin film increases as the concentration of Al₂O₃ decreases. For example, at a leakage current density threshold of less than approximately 2×10⁻⁶ Amps/cm², a nanolaminate thin film having an Al₂O₃ concentration of approximately forty-seven percent (47%) may have a dielectric breakdown field of approximately 11 MV/cm while a nanolaminate thin film having an Al₂O₃ concentration of approximately twenty-six percent (26%) may have a dielectric breakdown field of approximately 13 MV/cm.

As illustrated in FIG. 7B, the dielectric breakdown characteristics were measured for a nanolaminate film having an Al₂O₃ concentration ranging from approximately 26% to approximately 100% at current densities of approximately 2×10⁻⁶ Amps/cm² and approximately 2×10⁻⁵ Amps/cm². Again, the graph shows that the dielectric strength of nanolaminate films having lower Al₂O₃ concentrations breakdown at higher dielectric fields than films having a higher Al₂O₃ concentration. For example, an Al₂O₃/SiO₂ nanolaminate may have a breakdown field of greater than approximately 11 MV/cm for films having an Al₂O₃ concentration less than approximately 50% and a breakdown field of less than or equal to approximately 11 MV/cm for films having an Al₂O₃ concentration greater than approximately 50%.

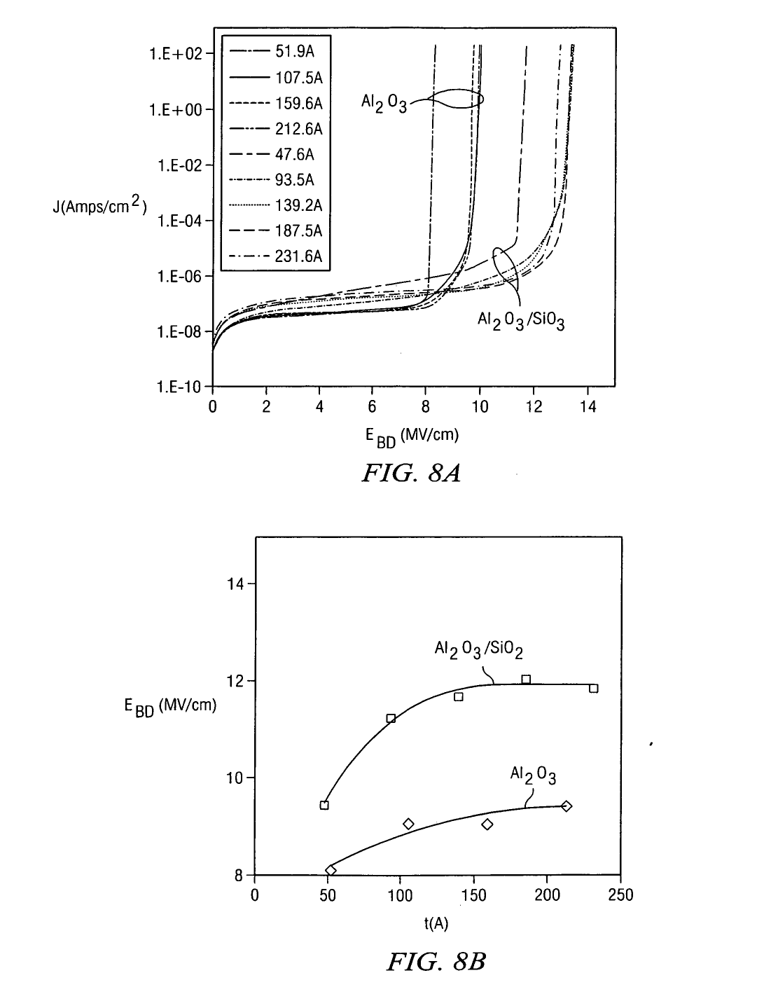

FIGS. 8A and 8B illustrate graphs of dielectric breakdown characteristics for a single layer of Al₂O₃ and a nanolaminate layer of Al₂O₃/SiO₂ deposited using an ALD process as a function of film thickness. As shown, the dielectric breakdown characteristics were measured for Al₂O₃ films at four different thicknesses ranging from approximately 52 Å to approximately 213 Å and nanolaminate films at five different thicknesses ranging from approximately 48 Å to approximately 232 Å. In the illustrated embodiment, a single Al₂O₃ film and a nanolaminate film of [10Al₂O_{3/1}SiO₂]ₙ (e.g., 10 layers of Al₂O₃ and 1 layer of SiO₂, which has a Al₂O₃ concentration of approximately 46%) were deposited at different thicknesses. As shown, the nanolaminate film exhibits higher breakdown field values by approximately 1.5 MV/cm to approximately 2.5 MV/cm over the thickness range at a leakage current density threshold less than approximately 2×10⁻⁶ Amps/cm².

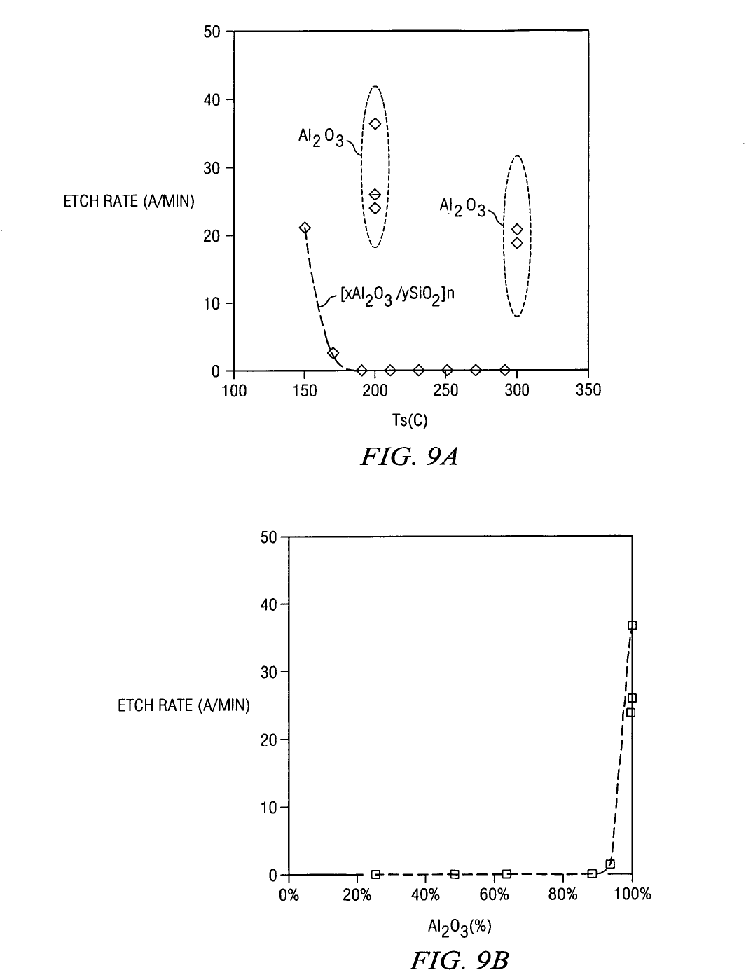

FIGS. 9A and 9B illustrate graphs of resist developer etch rates for a single layer of Al₂O₃ and a nanolaminate layer of Al₂O₃/SiO₂ deposited using an ALD process as a function of substrate temperature and a function of Al₂O₃ composition, respectively. As illustrated in FIG. 9A, the etch rates for a single Al₂O₃ layer and an Al₂O₃/SiO₂ nanolaminate were measured at eight different deposition temperatures ranging from approximately 150° C. to approximately 290° C. In addition to improvements in the dielectric breakdown strength of a nanolaminate Al₂O₃/SiO₂ film as illustrated above in FIGS. 7 and 8, Al₂O₃/SiO₂ nanolaminates may have an improved etch resistance to base solutions (e.g., photoresist developer). As shown, the etch rate of an Al₂O₃/SiO₂ nanolaminate for substrate temperatures greater than approximately 150° C. may be close to zero while the etch rate for a single layer of Al₂O₃ may be greater than or equal to approximately 20 Å/minute at temperatures greater than 150° C.

As illustrated in FIG. 9B, the etch rates were measured for Al₂O₃/SiO₂ nanolaminates having an Al₂O₃ concentration ranging from approximately 26% to approximately 100%. The etch rates for Al₂O₃/SiO₂ nanolaminates having Al₂O₃ concentrations of less than approximately 85% may be close to zero as compared to the films having an Al₂O₃ concentration of greater than 90% where the etch rates may be greater than approximately 20 Å/min.

FIG. 10 illustrates a graph of tensile strength of a nanolaminate film formed using an ALD process as a function of Al₂O₃ concentration. As shown, a single layer film of Al₂O₃ may have a tensile stress value of approximately 400 MPa while a single layer film of SiO₂ may have a tensile or compressive stress value of less than approximately 50 MPa. Thus, the film stress of an ALD nanolaminate thin film may be controllably reduced by adjusting the Al₂O₃ concentration.

Although the present invention has been described with respect to a specific preferred embodiment thereof, various changes and modifications may be suggested to one skilled in the art and it is intended that the present invention encompass such changes and modifications fall within the scope of the appended claims.

What is claimed is:

1. A method for forming a nanolaminate thin film using atomic layer deposition, comprising:
forming an aluminum oxide layer having a first thickness on at least a portion of a substrate surface by sequentially pulsing a first precursor and a first reactant into an enclosure containing the substrate; and
forming a silicon dioxide layer having a second thickness on at least a portion of the aluminum oxide layer by sequentially pulsing a second precursor and a second reactant into the enclosure to form a nanolaminate thin film.

2. The method of claim 1, wherein the nanolaminate thin film comprises a read head gap layer.

3. The method of claim 1, wherein:
the first precursor comprises trimethylaluminum (TMA); and
the first reactant is selected from the group consisting of water, ozone and oxygen radicals.

4. The method of claim 1, wherein:
the second precursor comprises TMA; and
the second reactant is selected from the group consisting of tris(tert-butoxy)silanol, tris(tert-pentoxy)silanol and tris(iso-propoxy)silanol.

5. The method of claim 1, further comprising the second thickness being greater than the first thickness such that the nanolaminate thin film has a concentration of aluminum oxide of less than approximately fifty percent.

6. The method of claim 1, further comprising a deposition temperature being in a range between approximately 150° C. and approximately 300° C.

7. The method of claim 6, further comprising forming the aluminum oxide layer at a first deposition rate of approximately 1.05 Å/cycle over the deposition temperature range.

8. The method of claim 6, wherein a deposition rate for the silicon dioxide layer varies between approximately 2.4 Å/cycle and approximately 13 Å/cycle over the deposition temperature range.

9. The method of claim 1, further comprising the nanolaminate thin film including a thickness of between approximately 50 Å and approximately 250 Å.

10. The method of claim 1, further comprising repeating the steps of forming the aluminum oxide layer and forming the silicon dioxide layer such that the nanolaminate thin film includes a plurality of alternating aluminum oxide and silicon dioxide layers.

11. The method of claim 1, further comprising:
introducing a purge gas into the enclosure after the first precursor and the first reactant such that substantially all of the first precursor and the first reactant are removed from the enclosure; and
introducing the purge gas into the enclosure after the second precursor and the second reactant such that substantially all of the second precursor and the second reactant are removed from the enclosure.

12. The method of claim 1, wherein the substrate surface comprises a layer of silicon dioxide having a third thickness formed by sequentially pulsing the second precursor and the second reactant into the enclosure.

13. An method for forming a nanolaminate thin film using atomic layer deposition (ALD), comprising:
forming an aluminum oxide layer having a first thickness on at least a portion of a substrate surface by sequentially pulsing trimethylaluminum (TMA) and water into an enclosure containing the substrate; and
forming a silicon dioxide layer having a second thickness on at least a portion of the aluminum oxide layer by sequentially pulsing TMA and tris(tert-butoxy)silanol into the enclosure to form a read head gap layer.

14. The method of claim 13, further comprising the second thickness being greater than the first thickness such that the nanolaminate thin film has a concentration of aluminum oxide of less than approximately fifty percent.

15. The method of claim 13, further comprising a deposition temperature being in a range of between approximately 150° C. and approximately 300° C.

16. The method of claim 15, further comprising:
forming the aluminum oxide layer at a first deposition rate of approximately 1.05 Å/cycle at the deposition temperature of approximately 210° C. forming the silicon dioxide layer at a second deposition rate of approximately 13 Å/cycle at the deposition temperature of approximately 210° C.

17. The method of claim 13, further comprising the read gap layer including a thickness of between approximately 50 Å and approximately 250 Å.

18. The method of claim 13, further comprising repeating the steps of forming the aluminum oxide layer and forming the silicon dioxide layer such that the read gap layer includes a plurality of alternating aluminum oxide and silicon dioxide layers.

19. A thin film, comprising:
an ALD-formed aluminum oxide layer having a first thickness, the aluminum oxide layer formed on at least a portion of a substrate surface; and
an ALD-formed silicon dioxide layer having a second thickness formed on at least a portion of the aluminum oxide layer, the aluminum oxide layer and the silicon dioxide layer cooperating to form a nanolaminate thin film.

20. The film of claim 19, wherein the nanolaminate thin film comprises a read head gap layer.

21. The film of claim 19, further comprising the second thickness being greater than the first thickness such that the nanolaminate thin film has a concentration of aluminum oxide of less than approximately fifty percent.

22. The film of claim 19, further comprising the nanolaminate thin film including a dielectric breakdown field in a range of between approximately 11 MV/cm and approximately 14 MV/cm.

23. The film of claim 19, further comprising the nanolaminate thin film including a stress in a range of between approximately 50 MPa and approximately 400 MPa based on an aluminum oxide concentration.

24. The film of claim 19, further comprising the nanolaminate thin film including an etch resistance to base solutions such that the etch rate of the nanolaminate film is approximately equal to zero.

25. The film of claim 19, further comprising the nanolaminate thin film including a thickness of between approximately 50 Å and approximately 250 Å.

26. The film of claim 19, further comprising:
a plurality of ALD-formed aluminum oxide layers having the first thickness, a bottom one of the aluminum oxide layers formed on the substrate surface; and
a plurality of ALD-formed silicon dioxide layers having the second thickness, the aluminum oxide layers alternating with the silicon dioxide layers to form the nanolaminate thin film.

27. The film of claim 19, further comprising a top ALD-formed aluminum oxide layer having a third thickness, the second aluminum oxide layer formed on at least a portion of the silicon dioxide layer, the aluminum oxide layers and the silicon dioxide layer cooperating to form the nanolaminate thin film.
